(19) United States
(12) Patent Application Publication
(10) Pub. No.: US 2018/0376620 A1
(43) Pub. Date: Dec. 27, 2018

(54) BACK COVER UNIT APPLIED TO HANDHELD ELECTRONIC DEVICE WITH HEAT CONDUCTION AND HEAT DISSIPATION EFFECT

(71) Applicant: ASIA VITAL COMPONENTS CO., LTD., New Taipel City (TW)

(72) Inventor: Hsiu-Wei Yang, New Taipel City (TW)

(21) Appl. No.: 16/058,994

(22) Filed: Aug. 8, 2018

Related U.S. Application Data
(63) Continuation-in-part of application No. 14/103,000, filed on Dec. 11, 2013, now Pat. No. 10,101,779.

(51) Int. Cl. H05K 7/20; F28F 21/04; F28F 21/08

(52) U.S. Cl. CPC H05K 7/20509; F28F 21/04; H04B 1/3888; G06F 2200/1633; F28F 21/084

(57) ABSTRACT

A back cover unit applied to handheld electronic device with heat conduction and heat dissipation effect includes a ceramic back cover having an outer surface and an inner surface. The inner surface faces a receiving space of a handheld electronic device. A cooling chip is disposed on the inner surface in contact with at least one heat source in the receiving space. The outer surface of the ceramic back cover faces an external environment, whereby the heat generated by the heat source can be transferred through the cooling chip to the ceramic back cover to dissipate the heat.

The present application is a continuation in part of U.S. patent application Ser. No. 14/103,000, filed on Dec. 11, 2013.

### BACKGROUND OF THE INVENTION

### 1. Field of the Invention

The present invention relates generally to heat dissipation field, and more particularly to a back cover unit with heat conduction and heat dissipation effect.

### 2. Description of the Related Art

A handheld electronic device is a sort of portable electronic device, which can be readily and conveniently operated and used by a user. Along with the progressive increase of the arrangement density of the components of the electronic device, the volume of the electronic device has become smaller and smaller and the weight of the electronic device has become lighter and lighter. As a result, along with the minimization of the size of the electronic device, the heat dissipation problem of the electronic device has become a critical issue bothering the product designer, especially in the field of handheld electronic device.

The case of a common handheld electronic device on the market is generally made of plastic material. The handheld electronic device has a quite small volume so that the size of the electronic components in the device is miniaturized. In this case, it is hard to conduct out the heat generated by the electronic components so that it is difficult to dissipate the heat of the handheld electronic device. As a result, the electronic components in the electronic device often fail due to overheating to shorten the lifetime of the electronic device or deteriorate the performance of the electronic device.

In addition, some manufacturers in this field manufacture the case of the handheld electronic device from a great amount of metal as the mail material of the case, especially aluminum/magnesium alloy. This is because aluminum/magnesium alloy has light weight and higher strength as well as excellent appearance. Aluminum/magnesium alloy has almost become the major material of the case of the new generation handheld electronic device. However, the aluminum/magnesium alloy-made case of the handheld electronic device simply has a more beautiful appearance than the common plastic-made case, while the aluminum/magnesium alloy-made case still has no heat dissipation effect so that the heat in the case is still hard to dissipate. Under such circumstance, the lifetime of the electronic components in the case will be still shortened due to overheating. Furthermore, the aluminum/magnesium alloy-made case will shield the antenna from the signal and affect the signal receiving ability of the antenna so that the aluminum/magnesium alloy-made case cannot satisfy the layout requirement of the antenna structure.

### SUMMARY OF THE INVENTION

It is therefore a primary object of the present invention to provide a back cover unit applied to handheld electronic with heat conduction and heat dissipation effect, which can conduct the heat inside the handheld electronic device to the ceramic back cover via a cooling chip for dissipating the heat.

It is a further object of the present invention to provide the above back cover unit including a ceramic back cover and at least one cooling chip connected with the ceramic back cover as a part of the case of the handheld electronic device. The ceramic back cover will not affect the signal of the antenna and serves as a heat dissipation path of the heat inside the handheld electronic device.

To achieve the above and other objects, the back cover unit applied to handheld electronic device with heat conduction and heat dissipation effect of the present invention includes a ceramic back cover having an outer surface and an inner surface. The inner surface faces a receiving space of a handheld electronic device. A cooling chip is disposed on the inner surface in contact with at least one heat source in the receiving space. The outer surface of the ceramic back cover faces an external environment, whereby the heat generated by the heat source can be transferred through the cooling chip to the ceramic back cover to dissipate the heat.

In the above back cover unit, the cooling chip has a cold end in contact with the heat source and a hot end in contact with the inner surface of the ceramic back cover.

In the above back cover unit, the cooling chip is disposed on the inner surface of the ceramic back cover in a position corresponding to the heat source and is overlapped with the ceramic back cover.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of the present invention;

FIG. 2A is a perspective assembled view of the present invention;

FIG. 2B is a perspective assembled view according to FIG. 2A, showing the other face of the present invention;

FIG. 3A is a view of the cooling chip of the present invention;

FIG. 3B is a sectional view of the ceramic back cover of the present invention;

FIG. 3C is a sectional view of another embodiment of the ceramic back cover of the present invention; and

FIG. 4 is a sectional view showing the application of the present invention.

### DETAILED DESCRIPTION OF THE PREFERRED EMBODIMENTS

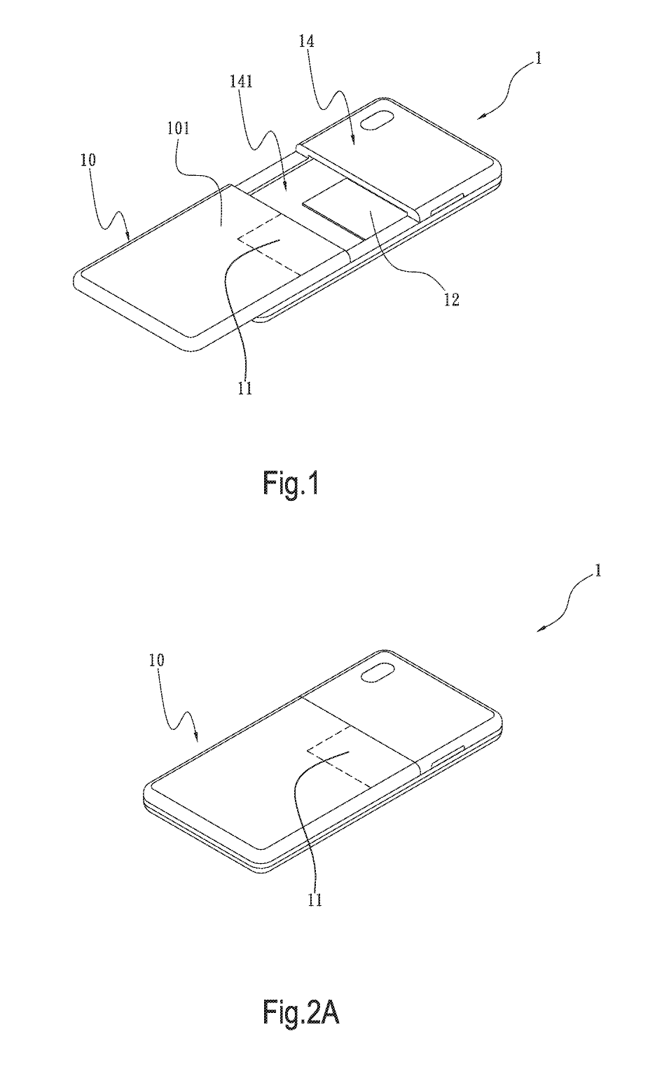

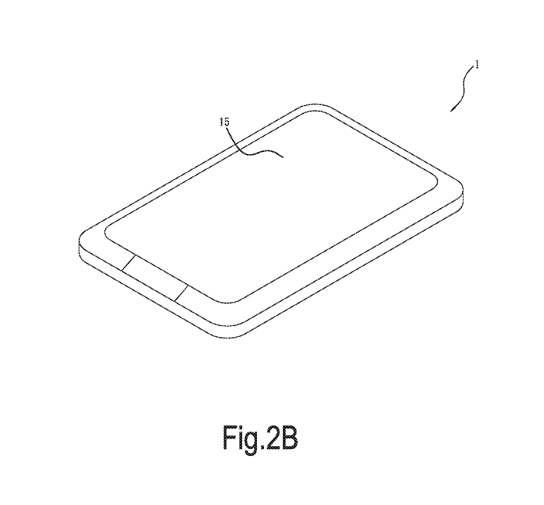

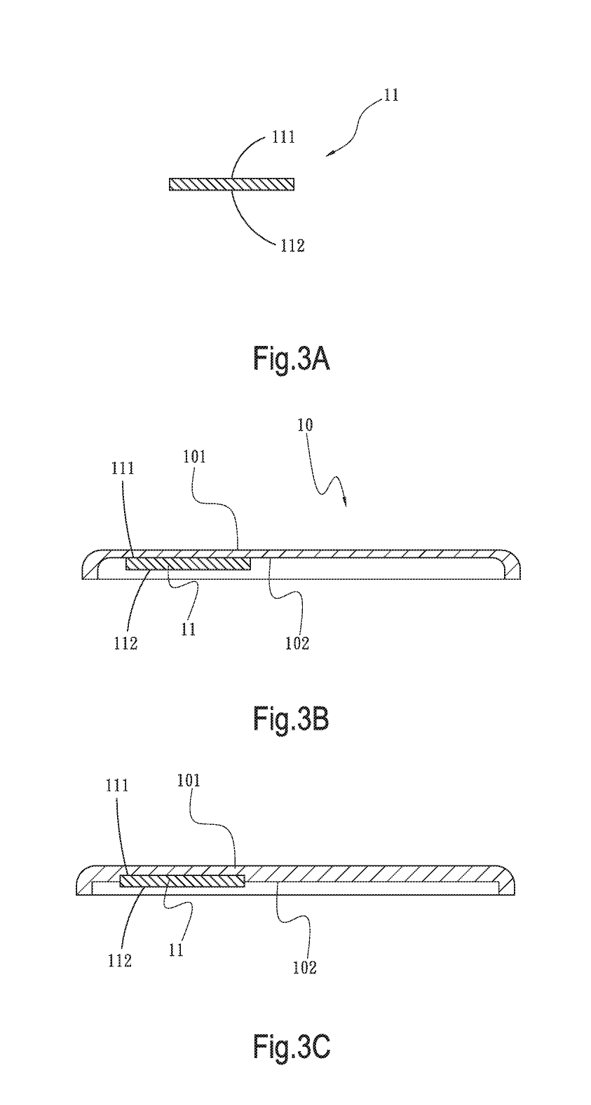

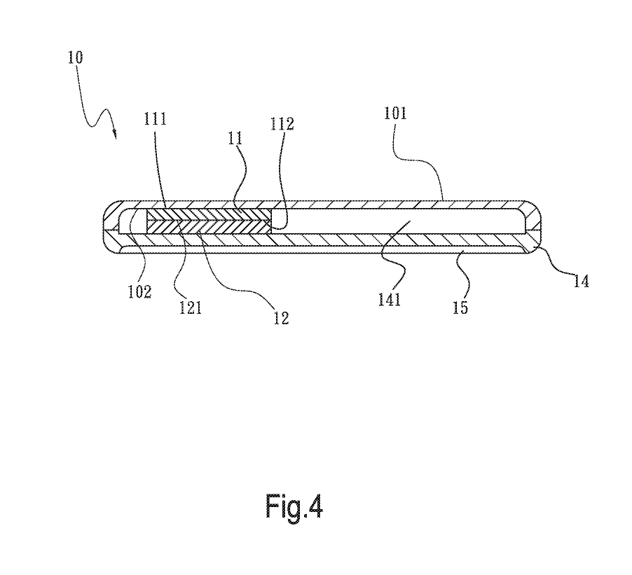

Please refer to FIGS. 1 to 4. FIG. 1 is a perspective exploded view of the present invention. FIG. 2A is a perspective assembled view of the present invention. FIG. 2B is a perspective assembled view according to FIG. 2A, showing the other face of the present invention. FIG. 3A is a view of the cooling chip of the present invention. FIG. 3B is a sectional view of the ceramic back cover of the present invention. FIG. 3C is a sectional view of another embodiment of the ceramic back cover of the present invention. FIG. 4 is a sectional view showing the application of the present invention. The back cover unit applied to handheld electronic device with heat conduction and heat dissipation effect of the present invention includes a ceramic back cover cooperatively assembled with a handheld electronic device 1 such as a cellular phone or a tablet. The handheld electronic device 1 has a case 14. One face of the case 14 defines a receiving space 141. A screen 15 such as a touch screen is disposed on the other face of the case 14. At least one side of the receiving space 141 is an open side. Components such as circuit boards and a battery are disposed in the receiving space 141. A heat source 12 is received in the receiving space 141. The heat source 12 is an electronic component (such as a CPU or an MCU) arranged on the circuit board or a battery.

The ceramic back cover 10 is made of a ceramic material such as zirconium oxide and/or aluminum oxide ceramics and has better elasticity, abrasion resistance and anti-scrape property. The ceramic material has another feature, that is, the ceramic material has good rigidity and can be manufactured with very thin thickness. In use, the ceramic material is uneasy to bend. The ceramic material will not affect the signal receiving ability of an antenna and can satisfy the layout requirement of 2G to 4G or 5G or even more advanced antenna structure. The ceramic back cover 10 has an outer surface 101 and an inner surface 102. The outer surface 101 is exposed to an external environment. The inner surface 102 faces the receiving space 141 of the handheld electronic device 1. A cooling chip 11 is disposed on the inner surface 102 in a position corresponding to at least one heat source. The cooling chip 11 is in direct or indirect contact with the heat source 12 in the receiving space 141, whereby the heat generated by the heat source 12 can be transferred through the cooling chip 11 to the outer surface 101 of the ceramic back cover 10 to dissipate the heat. After powered on, the cooling chip unit 11 has a hot end (heat releasing face) 111 and a cold end (heat absorption face) 112 respectively positioned on two sides of the cooling chip 11. The heat end 111 is in contact with the inner surface 102 of the ceramic back cover 10. The cold end 112 is in contact with a heat releasing surface 121 of the heat source 12. The cooling chip 11 is overlapped with the ceramic back cover 10, that is, a small area of the inner surface 102 of the ceramic back cover 10 is connected with the hot end 111 of the cooling chip 11 so that the layout and signal receiving ability of the antenna structure will not be affected. Moreover, the cooling chip 11 is connected with the inner surface 102 of the ceramic back cover 10 by means of adhesion and/or inlaying (as shown in FIGS. 3B and 3C).

In conclusion, in comparison with the conventional device, the present invention has the following advantages:
1. The cooling chip 11 with a heat conductivity higher than that of the ceramic back cover 10 is employed to quickly conduct the heat of the heat source 12 to the external environment.
2. The lifetime of the handheld electronic device is prolonged.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A back cover unit applied to handheld electronic device with heat conduction and heat dissipation effect, comprising a ceramic back cover having an outer surface and an inner surface, the inner surface facing a receiving space of a handheld electronic device, a cooling chip being disposed on the inner surface in contact with at least one heat source in the receiving space, the outer surface of the ceramic back cover facing an external environment, whereby the heat generated by the heat source can be transferred through the cooling chip to the ceramic back cover to dissipate the heat.

2. The back cover unit applied to handheld electronic device with heat conduction and heat dissipation effect as claimed in claim 1, wherein the cooling chip has a cold end in contact with the heat source and a hot end in contact with the inner surface of the ceramic back cover.

3. The back cover unit applied to handheld electronic device with heat conduction and heat dissipation effect as claimed in claim 1, wherein the cooling chip is disposed on the inner surface of the ceramic back cover in a position corresponding to the heat source and is overlapped with the ceramic back cover.
